(19) United States
(12) Patent Application Publication
(10) Pub. No.: US 2025/0140718 A1
(43) Pub. Date: May 1, 2025

(54) DIELECTRIC-FILLED BOND PADS IN CLIP PACKAGES

(71) Applicant: TEXAS INSTRUMENTS INCORPORATED, Dallas, TX (US)

(72) Inventors: Jose Arvin M. PLOMANTES, Dagupan (PH); Jeffrey Salvacion SOLAS, Iloilo City (PH)

(21) Appl. No.: 18/498,144

(22) Filed: Oct. 31, 2023

(51) Int. Cl. H01L 23/00

(52) U.S. Cl. CPC H01L 24/05; H01L 24/02; H01L 24/03; H01L 24/40; H01L 24/06; H01L 24/48; H01L 24/73; H01L 2224/0214; H01L 2224/02145; H01L 2224/0215; H01L 2224/0345; H01L 2224/03462; H01L 2224/05073; H01L 2224/05147; H01L 2224/05551; H01L 2224/05553; H01L 2224/05567; H01L 2224/05583; H01L 2224/05647; H01L 2224/05655; H01L 2224/05664; H01L 2224/0603; H01L 2224/06051; H01L 2224/40245; H01L 2224/48091; H01L 2224/48108; H01L 2224/48245; H01L 2224/48465; H01L 2224/73221

(57) ABSTRACT

A package comprises a semiconductor die including a device side having circuitry formed therein and a first metal member on the device side of the die and having a top surface facing away from the die. The first metal member includes a group of dielectric members, each dielectric member in the group of dielectric members extending at least partially through a thickness of the first metal member. The package also comprises solder material contacting the top surface of the first metal member and top surfaces of the dielectric members in the group of dielectric members. The package also includes a second metal member coupled to the solder material and to a conductive terminal of the package, the conductive terminal exposed to an exterior of the package.

### BACKGROUND

Semiconductor wafers are circular pieces of semiconductor material, such as silicon, that are used to manufacture semiconductor chips. Generally, complex manufacturing processes are used to form numerous integrated circuits on a single wafer. The formation of such circuits on a wafer is called fabrication. After wafer fabrication, the wafer is cut into multiple pieces, called semiconductor dies, with each die containing one of the circuits. The cutting, or sawing, of the wafer into individual dies is called singulation. Dies are then coupled to a lead frame and are covered by a mold compound, which is subsequently sawn to produce a package.

### SUMMARY

A package comprises a semiconductor die including a device side having circuitry formed therein and a first metal member on the device side of the die and having a top surface facing away from the die. The first metal member includes a group of dielectric members, each dielectric member in the group of dielectric members extending at least partially through a thickness of the first metal member. The package also comprises solder material contacting the top surface of the first metal member and top surfaces of the dielectric members in the group of dielectric members. The package also includes a second metal member coupled to the solder material and to a conductive terminal of the package, the conductive terminal exposed to an exterior of the package.

A method for manufacturing a package comprises sputtering a seed layer on a device side of a semiconductor wafer in which circuitry is formed; covering the seed layer with a photoresist; performing photolithography on the photoresist to form a cavity in the photoresist; and electroplating a metal member in the cavity of the photoresist and on the device side of the wafer. The method also comprises removing the photoresist and parts of the seed layer to produce cavities within the metal member and applying a dielectric member on the metal member and in the cavities within the metal member. The method also comprises exposing the dielectric member using a reticle including first portions having a first degree of opacity and second portions having a second degree of opacity. where the first portions of the reticle are vertically aligned with the cavities in the metal member. The method includes developing the dielectric member to remove portions of the dielectric member. The exposing and the developing cause portions of the dielectric member outside of the cavities in the metal member to be removed and portions of the dielectric member within the cavities of the metal member to have top surfaces that are approximately flush with a top surface of the metal member.

### BRIEF DESCRIPTION OF THE DRAWINGS

FIG. 1A is a profile, cross-sectional view of a clip package including dielectric-filled bond pads, in accordance with various examples.

FIG. 1B is a top-down view of a clip package including dielectric-filled bond pads, in accordance with various examples.

FIG. 1C is a perspective view of a clip package including dielectric-filled bond pads, in accordance with various examples.

FIG. 2 is a flow diagram of a method for manufacturing a clip package including dielectric-filled bond pads, in accordance with various examples.

FIGS. 3A1-3K3 are a process flow depicting the manufacture of a clip package including dielectric-filled bond pads, in accordance with various examples.

FIG. 4 is an electronic device including a clip package having dielectric-filled bond pads, in accordance with various examples.

### DETAILED DESCRIPTION

During the fabrication stage, circuits and various types of metal members (e.g., copper bond pads) are added to the device side of a semiconductor wafer. The metal members can have high densities, and during the fabrication stage, the high density of the metal members can physically warp the wafer such that the wafer is no longer usable. The density of the metal members can be reduced by forming multiple cavities in the metal members, and this reduced density causes the wafer warpage to be reduced or eliminated.

However, the formation of cavities in the metal members presents additional technical challenges. For example, a clip may be useful to couple a metal member to a package conductive terminal (e.g., a package lead or other metal member that is exposed to an exterior of the package). The clip may be coupled to the metal member using a solder paste, and this solder paste may at least partially fill the cavities in the metal member. In such situations, voiding will frequently occur in the solder paste present within the cavities, and this voiding results in mechanical instability (e.g., crack formation in the solder paste), which can compromise the functional and structural integrity of the package. The voiding can also cause difficulty distinguishing between voids and significant manufacturing defects during quality control inspections, which can result in false positives during inspection and reduce yield.

This disclosure describes various examples of packages that mitigate the technical challenges described above by filling the metal member cavities with dielectric material during the wafer fabrication stage of manufacture. Solder paste is then applied to the top surfaces of the dielectric material and the metal member, and a clip is attached using the solder paste. The clip is also attached to a conductive terminal. By filling the metal member cavities with dielectric material prior to applying solder paste, the solder paste is prevented from entering the cavities, and thus the problematic voiding described above is eliminated. Consequently, solder paste cracks do not form, and false positives during quality control inspections are reduced. In addition, the solder paste forms a smooth, flat, and even surface, thus facilitating a strong connection to the clip. In examples, a package comprises a semiconductor die including a device side having circuitry formed therein. The package comprises a first conductive (e.g., metal) member on the device side of the die and having a top surface facing away from the die, with the first metal member including a group of dielectric members, and each dielectric member in the group of dielectric members extending at least partially through a thickness of the first metal member. The package also comprises solder material contacting the top surface of the first metal member and top surfaces of the dielectric members in the group of dielectric members. The package also includes a second metal member coupled to the solder material and to a conductive terminal of the package, with the conductive terminal exposed to an exterior of the package.

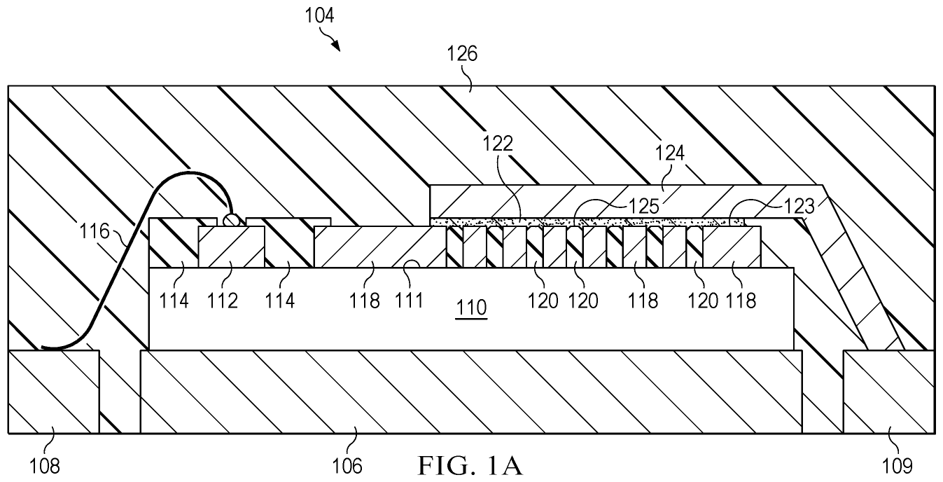

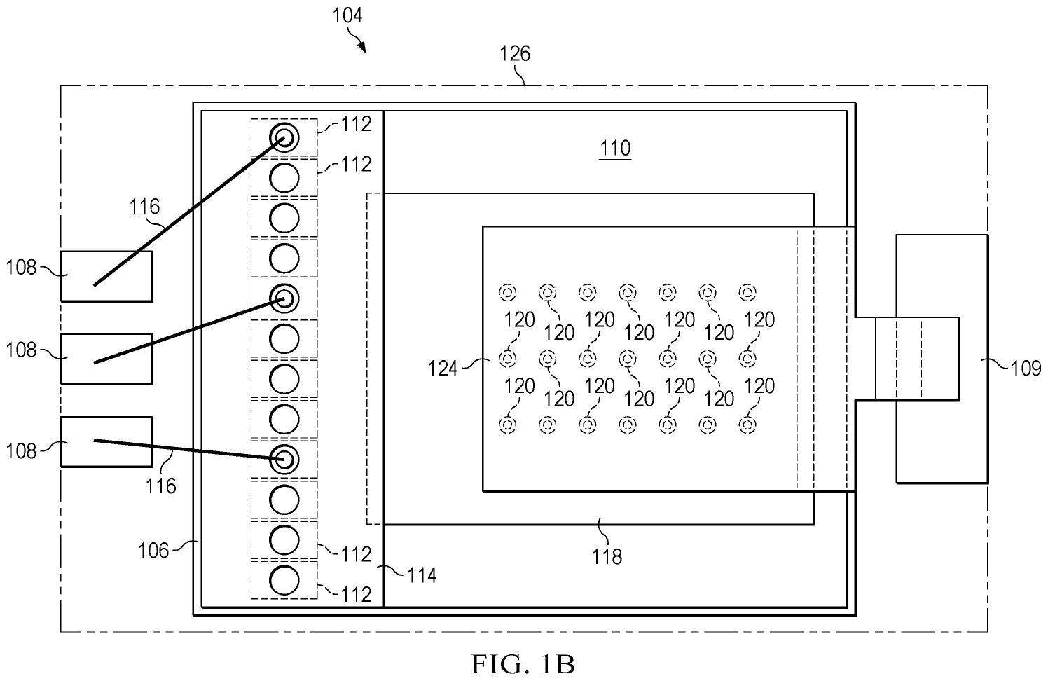

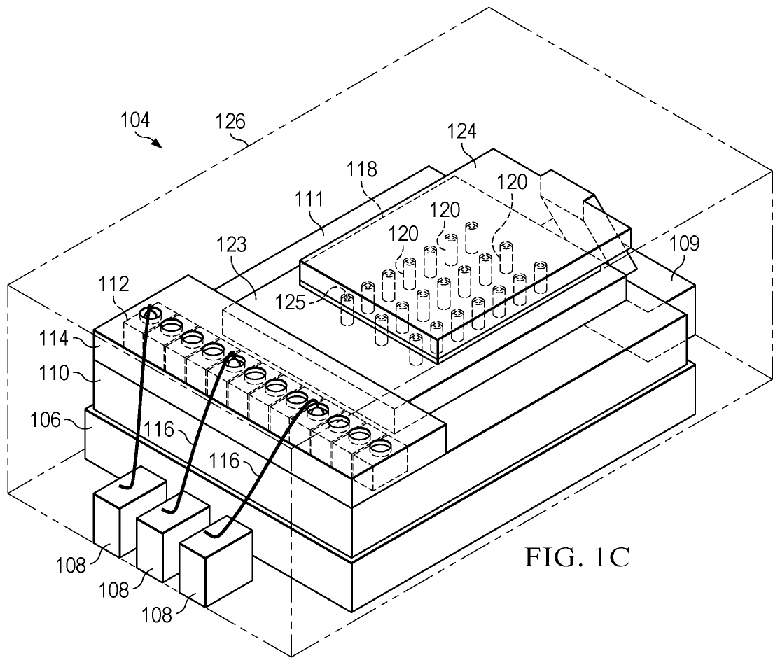

FIG. 1A is a profile, cross-sectional view of a clip package 104 including dielectric-filled bond pads, in accordance with various examples. The package 104 may include a die pad 106 and conductive terminals 108, 109. The package 104 is depicted as being a quad flat no lead (QFN) package, but the package 104 may be any suitable type of package in which a clip is coupled to a metal member inside the package. A clip may be defined herein as a rigid, non-wire metal member that couples a semiconductor die (or a metal member coupled to the semiconductor die, such as a bond pad) to one or more conductive terminals (e.g., metal members, such as package leads, that are exposed to an exterior of the package to couple to a substrate such as a printed circuit board) of the package. The structures described herein may also be useful in packages that have other types of metal members coupled to semiconductor dies in manners similar to a clip, for example, a heat sink. All such metal members are contemplated and included in the scope of this disclosure.

The package 104 may include a semiconductor die 110 coupled to the die pad 106 by way of a die attach material. The die 110 includes a device side 111 in which circuitry is formed. A bond pad 112 is coupled to the device side 111. A dielectric layer 114, which may include polyimide, a passivation overcoat, polyimide stacked on top of a passivation overcoat, or some other dielectric material(s), contacts the device side 111 and surrounds the bond pad 112. A bond wire 116 couples the bond pad 112 to the conductive terminal 108. Suitable types of wire bonds, such as ball bonds, stitch bonds, etc., may be useful.

The package 104 also includes a metal member 118 (e.g., a bond pad). In examples, the metal member 118 is a stack of metals, with a base or first layer of copper, a second or middle layer of nickel, and a third or top layer of palladium. Other combinations of metals and/or alloys are contemplated and included in the scope of this disclosure. The density of the metal member 118 is reduced relative to the density that the metal member 118 would otherwise have by the inclusion of multiple dielectric members 120 in the metal member 118. The dielectric members 120 are vertically oriented, extending through a thickness of the metal member 118, such that the dielectric members 120 make contact with the device side 111. In some examples, a thin layer of the metal member 118 is positioned between each of the dielectric members 120 and the device side 111 to prevent contact between the dielectric members 120 and the device side 111.

The package 104 includes a solder paste 122 on a top surface 123 of the metal member 118. The solder paste 122 contacts the top surface 123 and the top surfaces 125 of the dielectric members 120. The package 104 includes a clip 124 coupled to the top surfaces 123, 125 by the solder paste 122. The clip 124 is also coupled to the conductive terminal 109, as shown. FIG. 1B is a top-down view of the package 104, in accordance with various examples. FIG. 1C is a perspective view of the package 104, in accordance with various examples.

As described in more detail below, the dielectric members 120 are formed by filling cavities of the metal member 118 with dielectric material. To avoid voiding in the dielectric members 120 and the challenges associated with voiding (such as those described herein), the dielectric material is a polyimide or other material having a suitably low viscosity. The dielectric material forming the dielectric members 120 has a viscosity in the range of 3550 millipascal-second (mPa-s) to 3650 mPa-s, with a viscosity lower than this range being disadvantageous because it results in runoff and dripping, unacceptably poor adhesion, and unacceptably long curing times, and with a viscosity above this range being disadvantageous because it is unacceptably poor at filling cavities in which the dielectric members 120 are formed, has limited flow, and entraps air during application. The top surfaces 125 of the dielectric members 120 are approximately flush with the top surface 123 of the metal member 118, meaning that the top surfaces 125 are within 1 micron above or below the top surface 123. A difference between the top surfaces 123, 125 greater than this threshold is disadvantageous because it may encourage the formation of voids within the solder paste 122, as well as an uneven and thus weak mechanical connection to the clip 124. In examples, no dielectric material is present on the top surface 123.

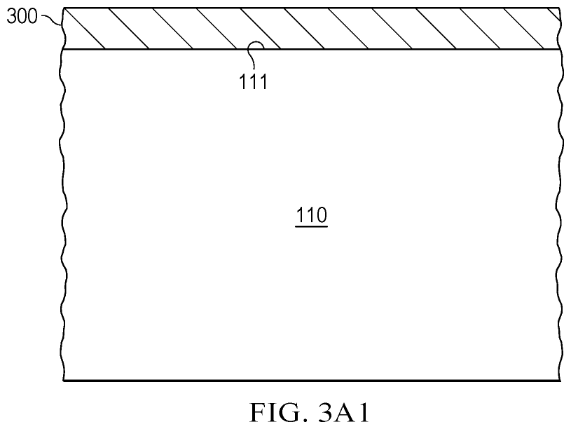

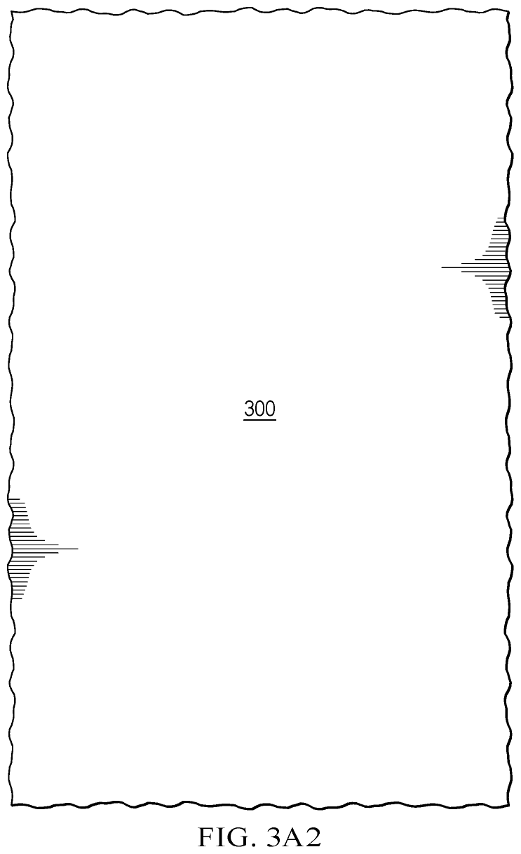

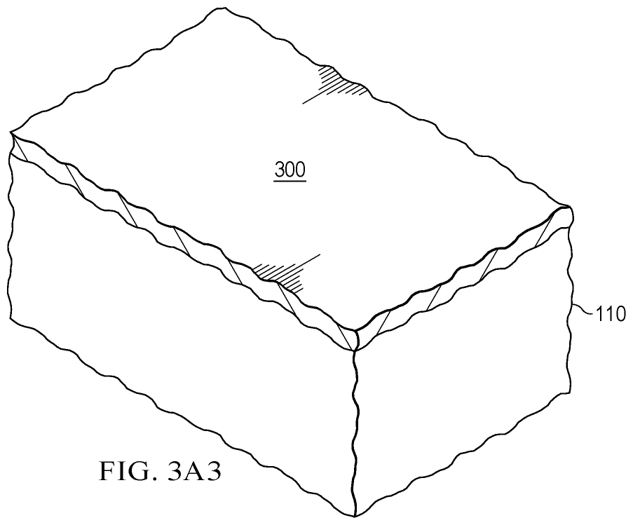

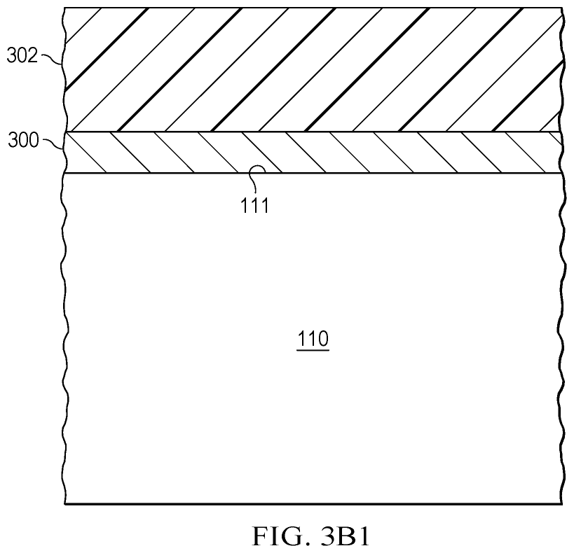

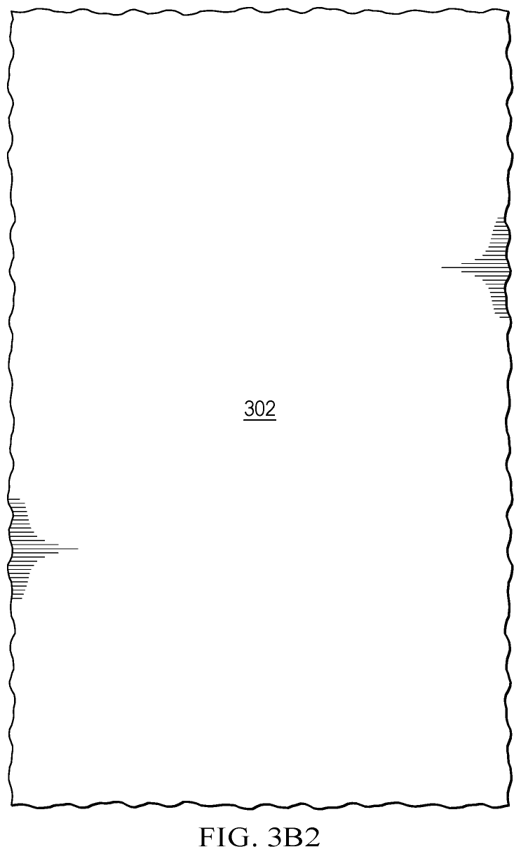

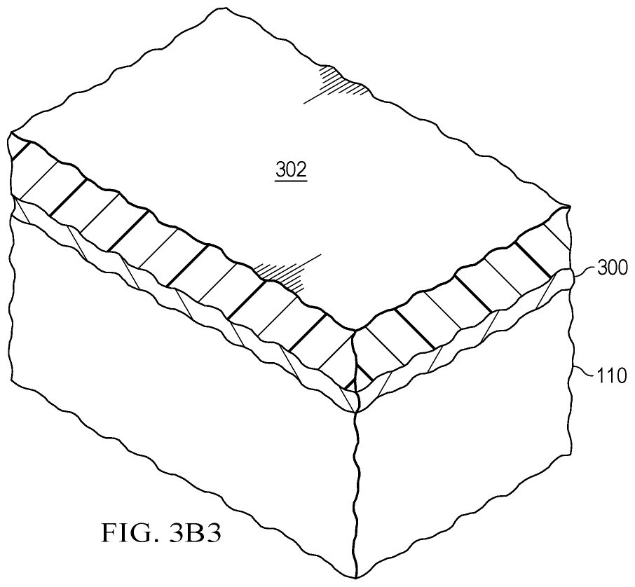

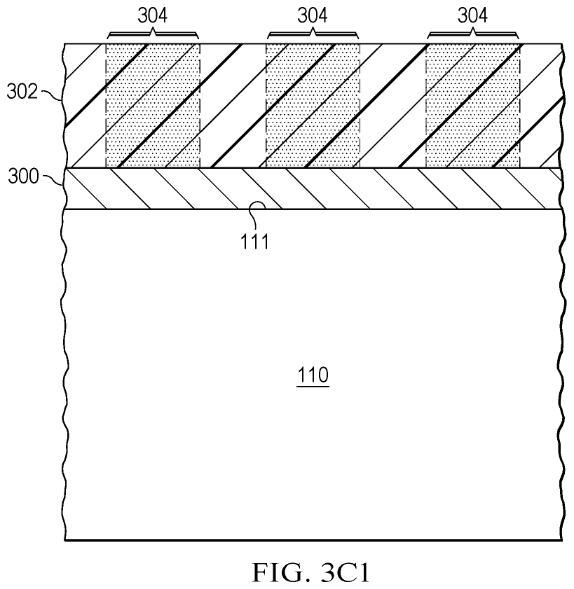

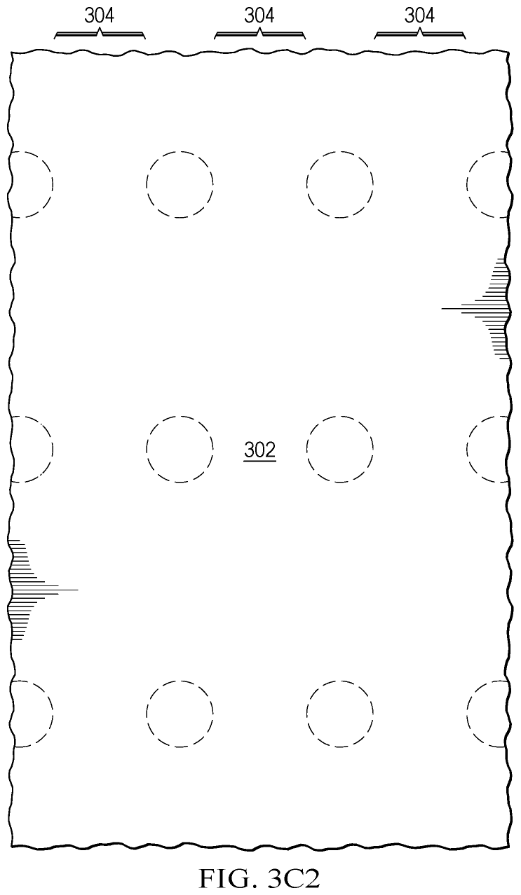

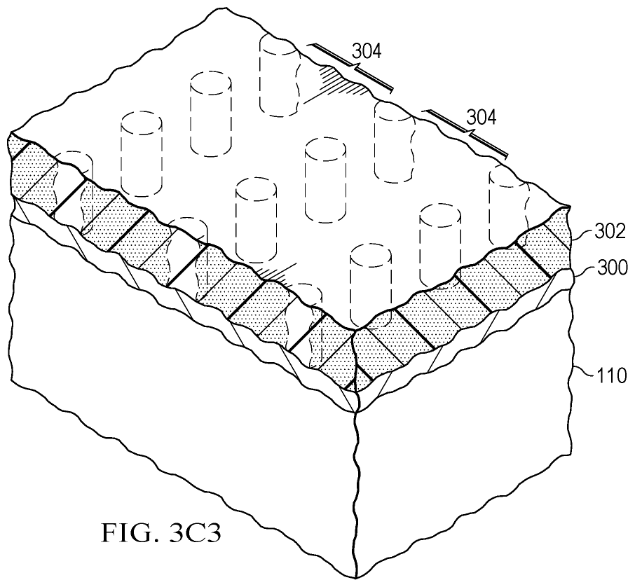

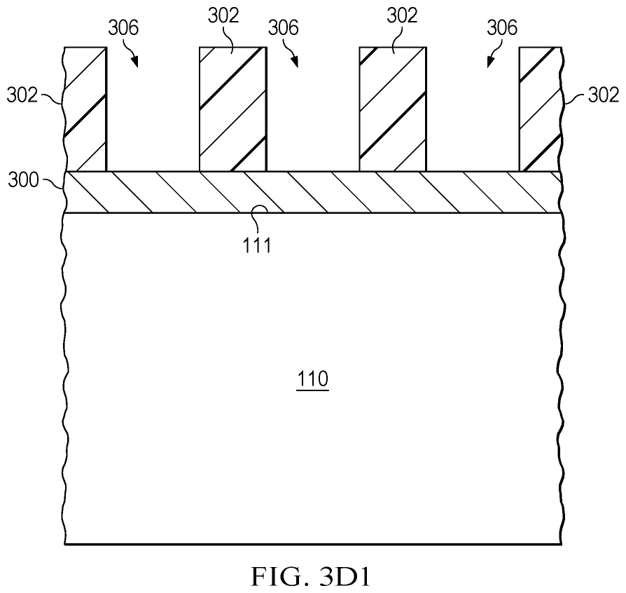

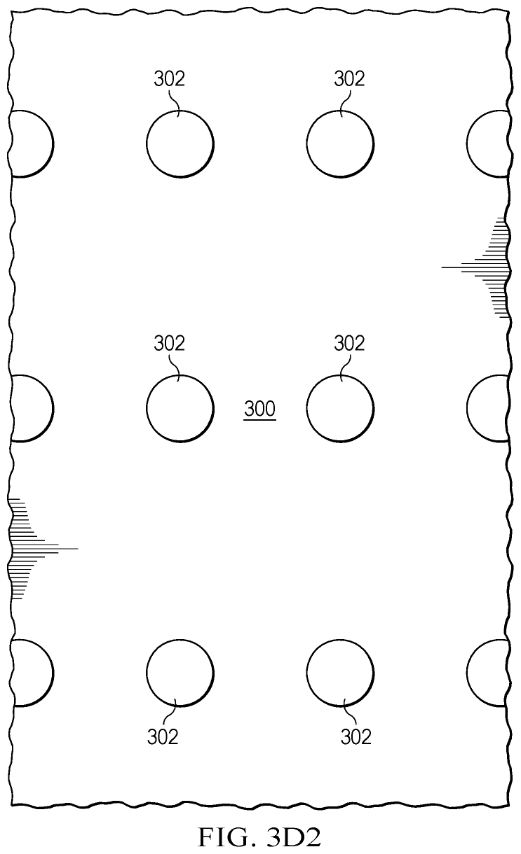

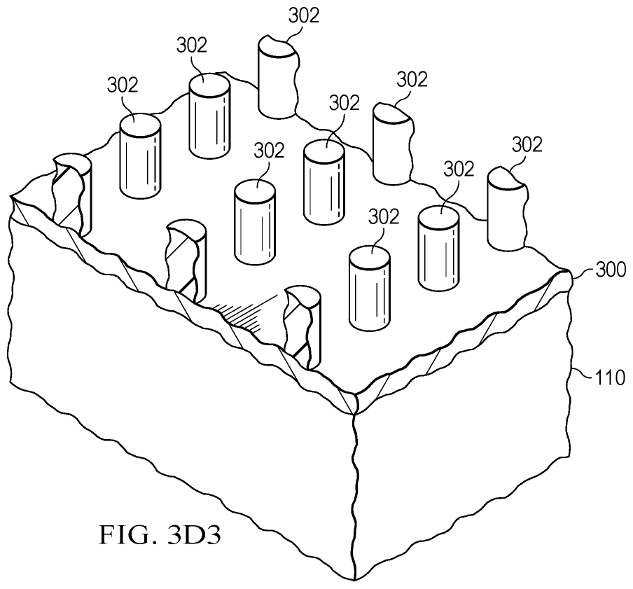

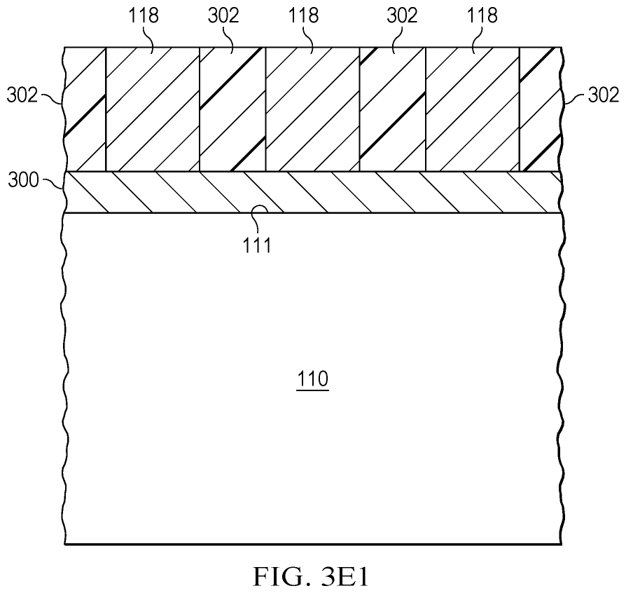

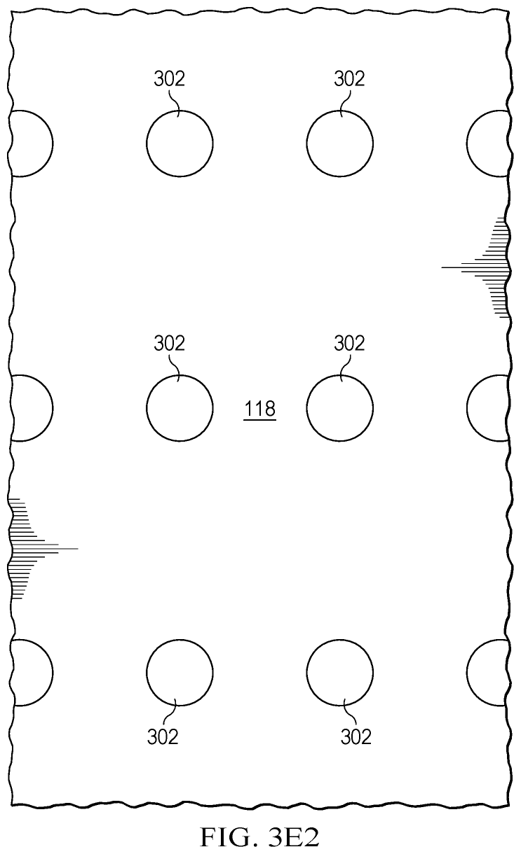

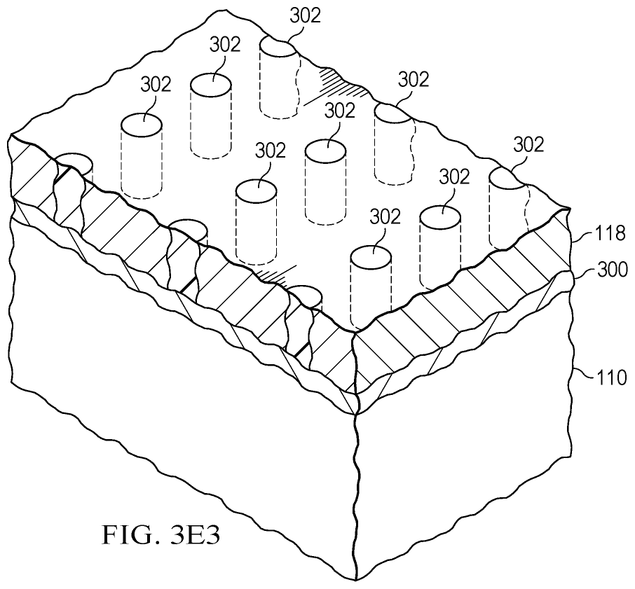

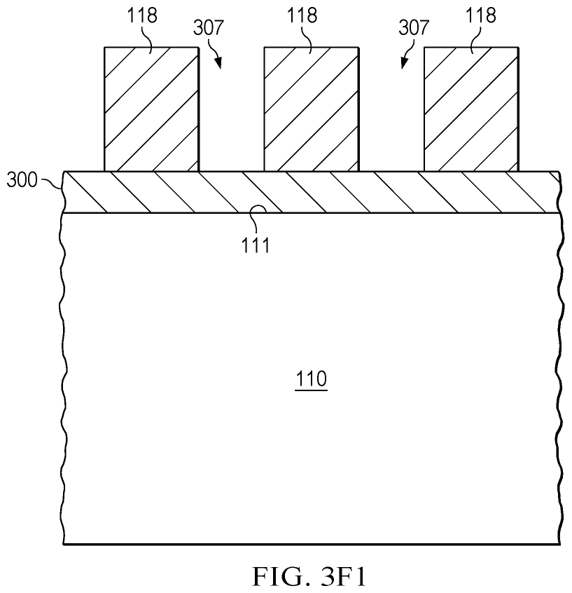

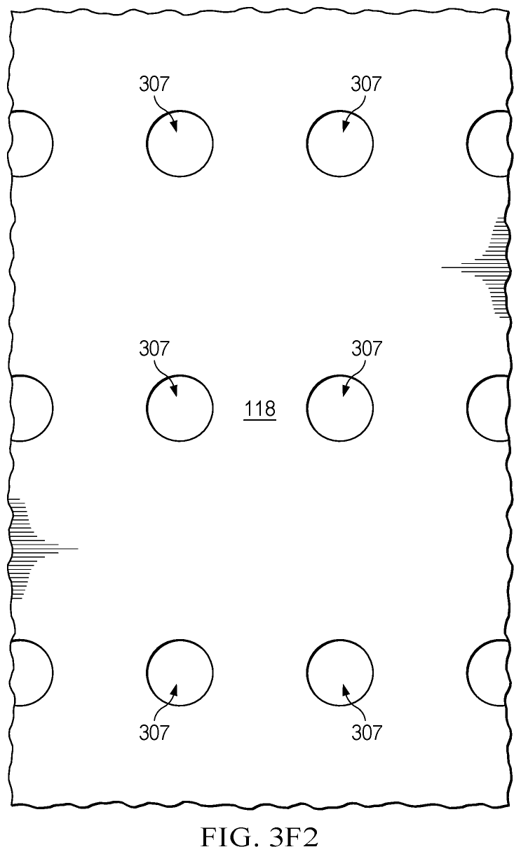

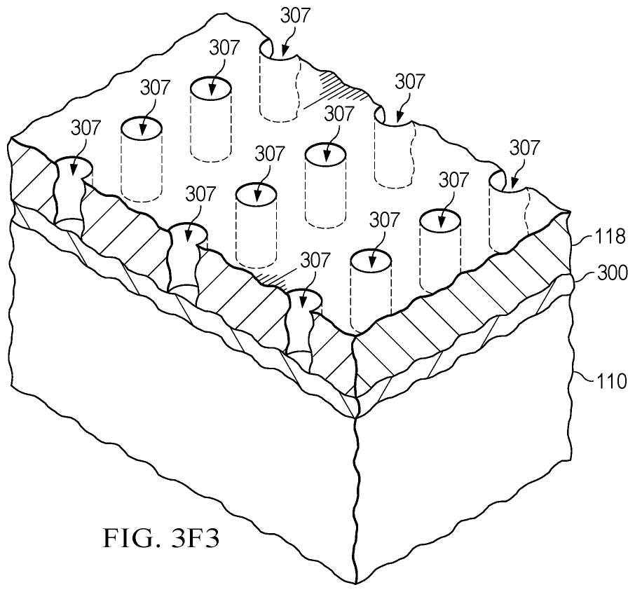

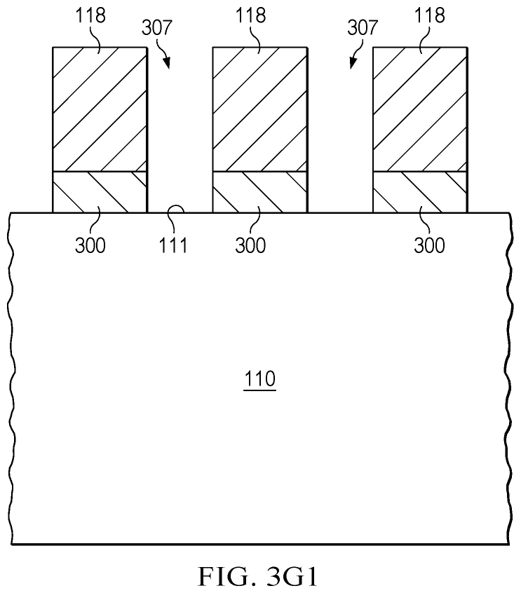

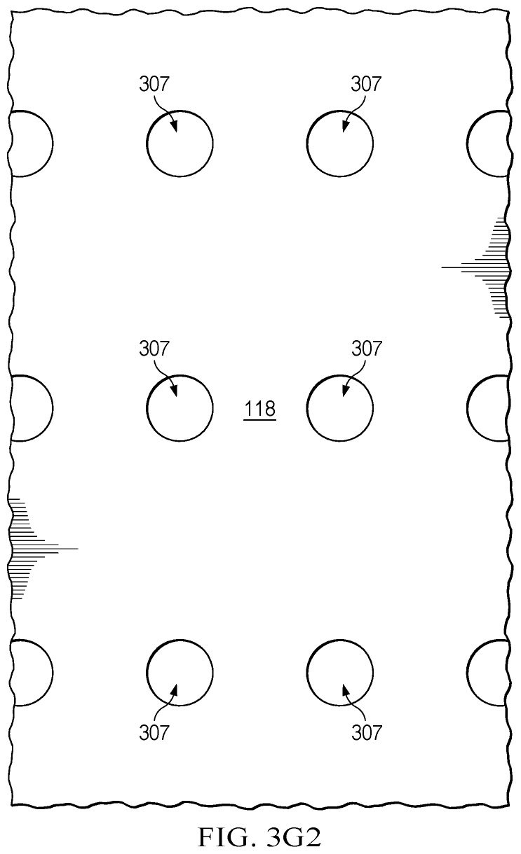

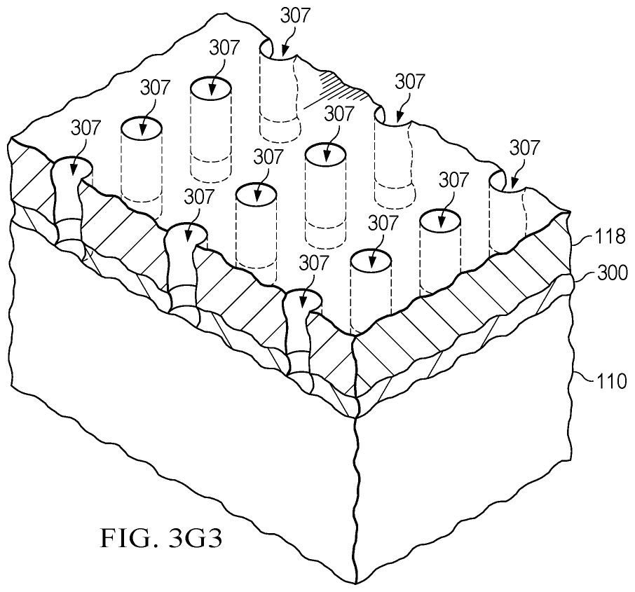

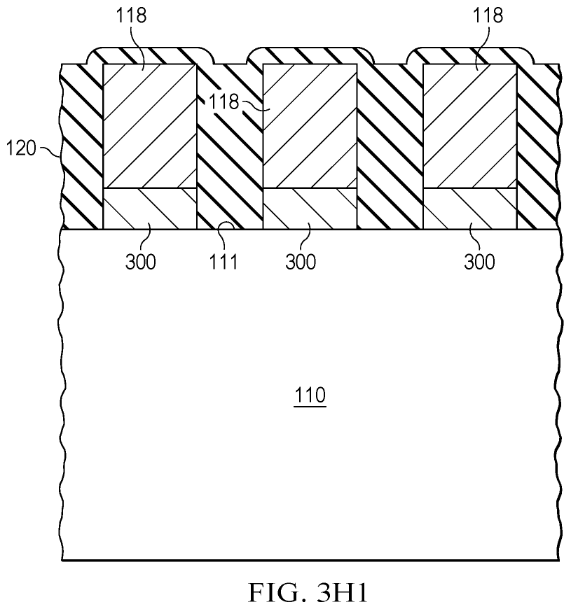

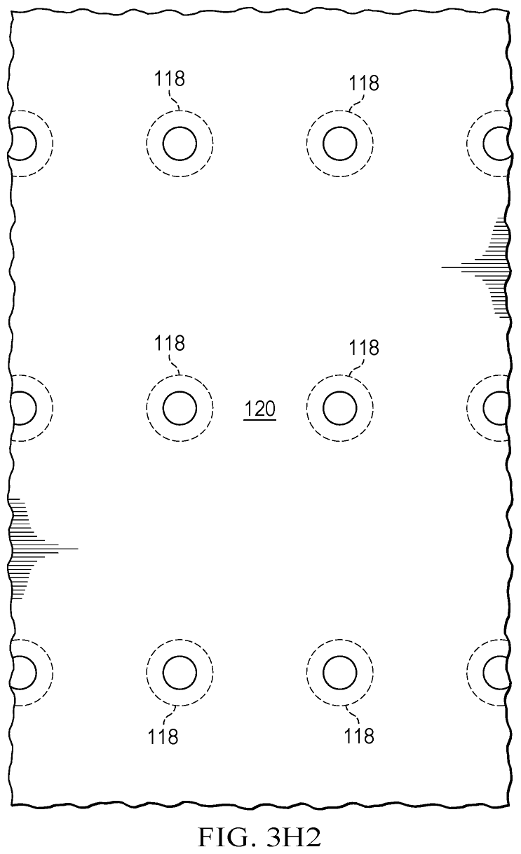

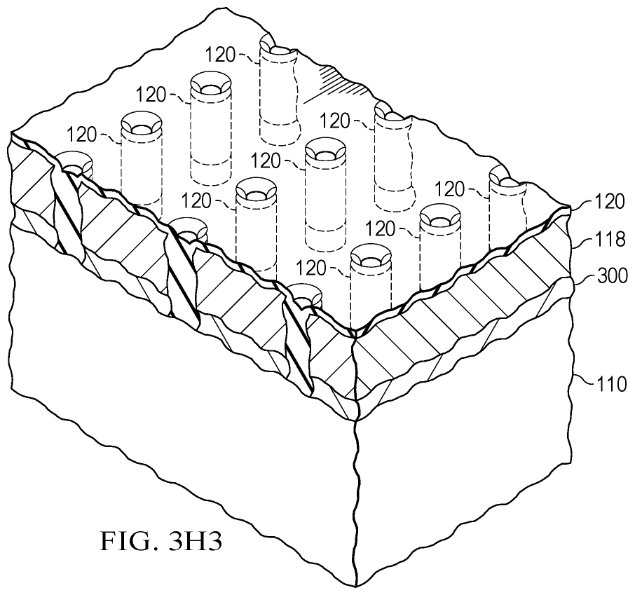

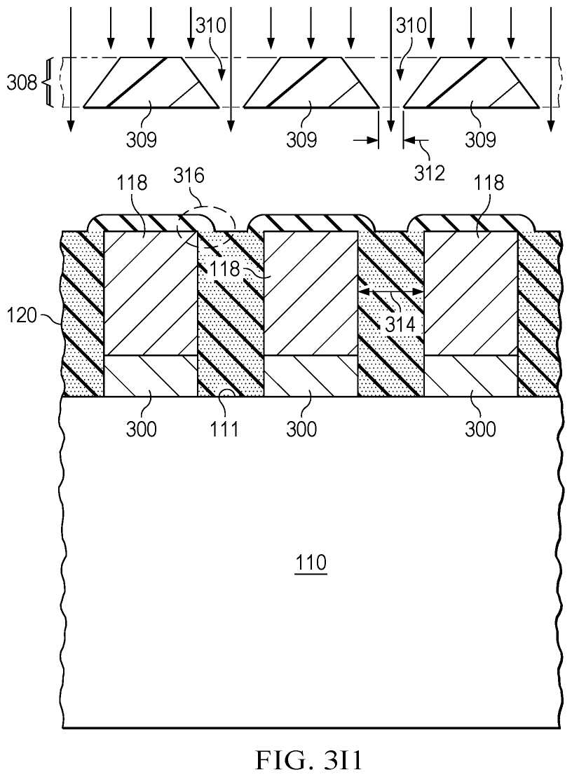

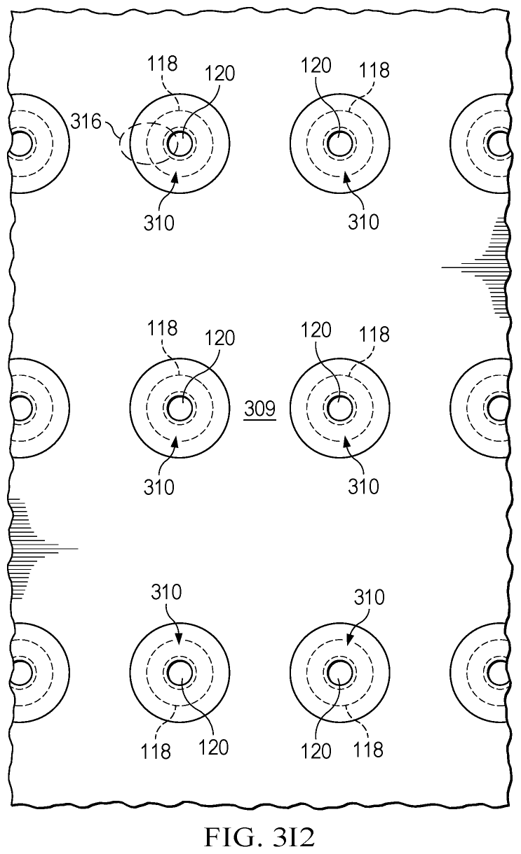

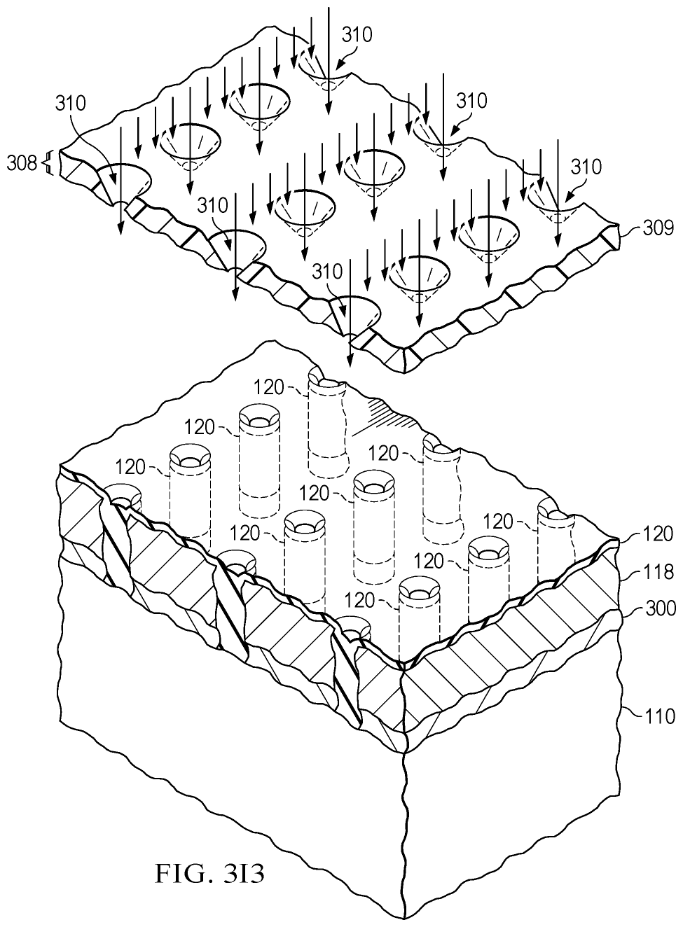

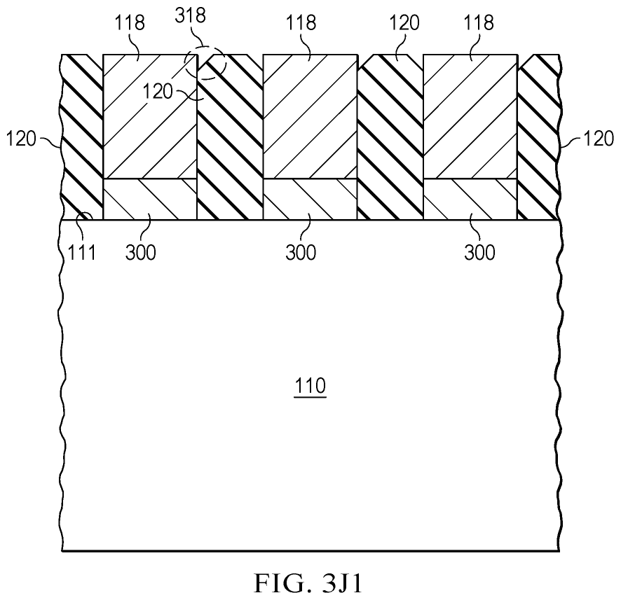

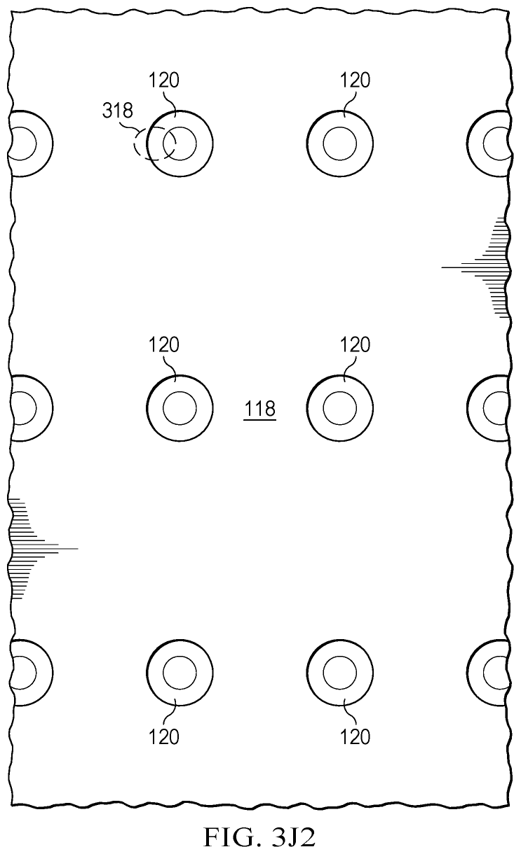

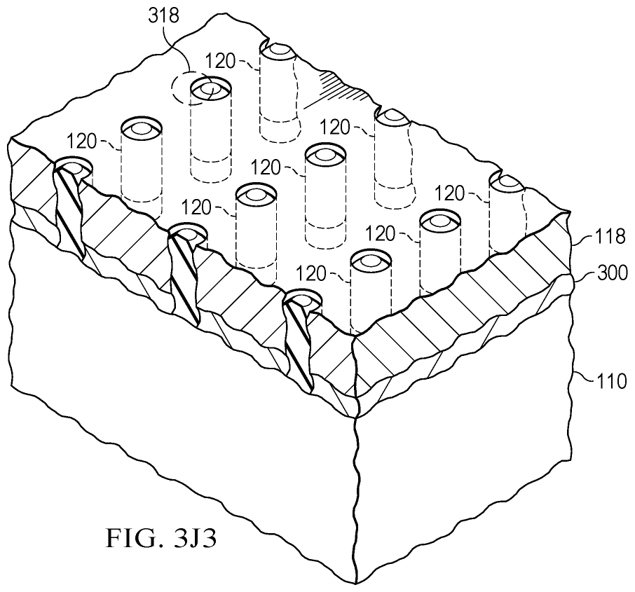

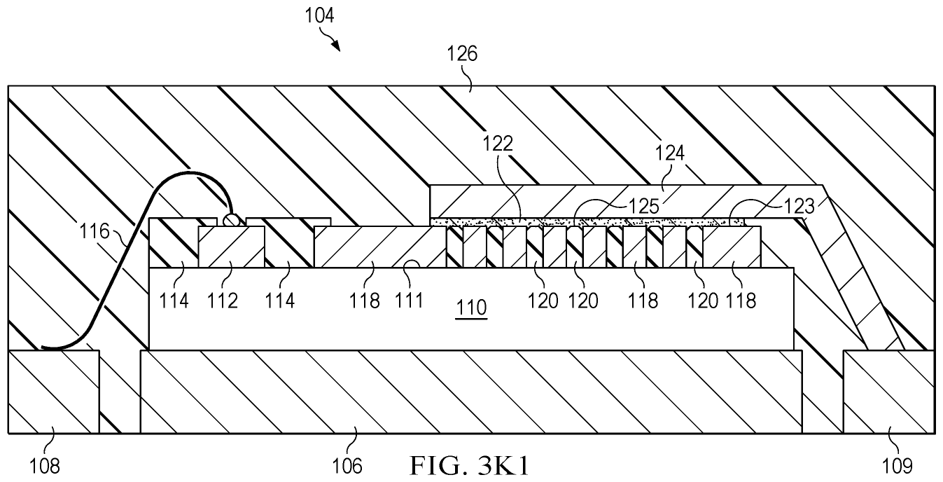

The top surfaces 125 are not necessarily completely flat. For example, as depicted in FIG. 3J1 (described below), the top surfaces 125 may have flat central areas that are flush with the top surface 123, but may also have downward slanted areas where the top surfaces 125 meet the top surface 123. These downward slanted areas of the top surfaces 125 near the top surface 123 do not contribute significantly to the voiding and/or uneven clip 124 coupling issues described above, so long as they do not dip below the surface 123 by more than 2.88 microns.

The density of the dielectric members 120 within the metal member 118 ranges from 20% to 40%, with a density below this range being disadvantageous because the material becomes prone to warpage due to increased density of the metal member 118, and with a density above this range being disadvantageous because of increased resistance, limited integration, and reduced electrical conductivity. Each of the dielectric members 120 has horizontal cross-sectional dimensions ranging from 10.42 microns to 16.18 microns, with a dimension below this range being disadvantageous because voiding occurs near the metal member 118 and dielectric member 120 region, and with a dimension above this range being disadvantageous because voiding occurs at the metal member 118 and clip 124 interface. A mold compound 126 covers the remaining structures of the package 104.

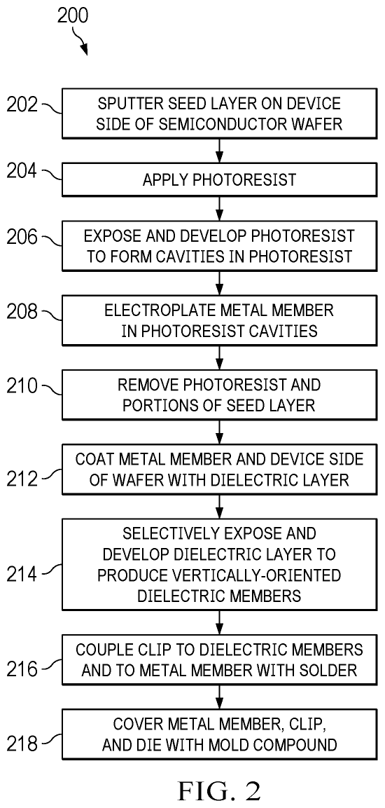

FIG. 2 is a flow diagram of a method 200 for manufacturing a clip package including dielectric-filled bond pads, in accordance with various examples. FIGS. 3A1-3K3 are a process flow depicting the manufacture of a clip package including dielectric-filled bond pads, in accordance with various examples. Accordingly, FIGS. 2 and 3A1-3K3 are now described in parallel.

The method 200 includes sputtering a seed layer on a device side of a semiconductor die (202). FIG. 3A1 is a profile, cross-sectional view of a semiconductor wafer 110 (which may also be referred to herein as a semiconductor die 110, as the steps of the method 200 may be performed during the wafer fabrication stage and/or during the post-singulation stage). A copper seed layer 300 is sputtered on the device side 111 of the wafer 110 in which circuitry is formed. FIG. 3A2 is a top-down view of the structure of FIG. 3A1, in accordance with various examples. FIG. 3A3 is a perspective view of the structure of FIG. 3A1, in accordance with various examples.

The method 200 includes applying a photoresist layer to the seed layer (204). FIG. 3B1 is a profile, cross-sectional view of the structure of FIG. 3A1, except that a photoresist layer 302 is applied on top of the seed layer 300, in accordance with various examples. The thickness of the photoresist layer 302 is the same as the target thickness of the metal member 118 (FIG. 1A). FIG. 3B2 is a top-down view of the structure of FIG. 3B1, in accordance with various examples. FIG. 3B3 is a perspective view of the structure of FIG. 3B1, in accordance with various examples.

The method 200 includes exposing and developing the photoresist layer to form cavities in the photoresist layer (206). FIG. 3C1 is a profile, cross-sectional view of the structure of FIG. 3B1, except that photolithographic techniques have been used to expose areas 304 of the photoresist layer 302, in accordance with various examples. FIG. 3C2 is a top-down view of the structure of FIG. 3C1, in accordance with various examples. FIG. 3C3 is a perspective view of the structure of FIG. 3C1, in accordance with various examples. FIG. 3D1 is a profile, cross-sectional view of the structure of FIG. 3C1, except that the exposed areas 304 of the photoresist layer 302 have been developed and removed, leaving cavities 306 in the photoresist layer 302, as shown. FIG. 3D2 is a top-down view of the structure of FIG. 3D1, in accordance with various examples. FIG. 3D3 is a perspective view of the structure of FIG. 3D1, in accordance with various examples. The cavities 306 are not individual cavities, but instead are fluidically connected to each other, and in this sense, the cavities 306 can be considered to be a single cavity 306 including multiple members of the remaining photoresist layer 302 that have not yet been removed.

The method 200 includes electroplating a metal member in the photoresist cavities (208). FIG. 3E1 is a profile, cross-sectional view of the structure of FIG. 3D1, except that the cavities 306 have been filled with electroplated metals (e.g., a stack of copper, nickel on top of the copper, and palladium on top of the nickel). As described above, the cavities 306 are fluidically connected, and so the electroplating produces a single, monolithic metal member 118. This monolithic aspect of the metal member 118 is visible in the top-down view of FIG. 3E2 and in the perspective view of FIG. 3E3, both of which are provided in accordance with various examples.

The method 200 includes removing the photoresist and portions of the seed layer (210). FIG. 3F1 is a profile, cross-sectional view of the structure of FIG. 3E1, except that the remaining members of the photoresist layer 302 are stripped away. FIG. 3F2 is a top-down view of the structure of FIG. 3F1, in accordance with various examples. FIG. 3F3 is a perspective view of the structure of FIG. 3F1, in accordance with various examples. FIG. 3G1 is a profile, cross-sectional view of the structure of FIG. 3F1, except that the areas of the seed layer 300 that are not directly below the metal member 318 are etched away, leaving multiple cavities 307 in the metal member 318. FIG. 3G2 is a top-down view of the structure of FIG. 3G1, in accordance with various examples. FIG. 3G3 is a perspective view of the structure of FIG. 3G1, in accordance with various examples.

The method 200 includes coating the metal member and the device side of the die with a dielectric member (212). FIG. 3H1 is a profile, cross-sectional view of the structure of FIG. 3G1, except that a dielectric member 120, such as polyimide, has been applied to the device side 111 and the metal member 318, as shown. The dielectric member 120 fills the cavities 307 of the metal member 318. FIG. 3H2 is a top-down view of the structure of FIG. 3H1, in accordance with various examples. FIG. 3H3 is a perspective view of the structure of FIG. 3H1, in accordance with various examples.

The method 200 includes selectively exposing and developing the dielectric member to produce vertically-oriented dielectric members (214). FIG. 3I1 is a profile, cross-sectional view depicting the exposure of the structure shown in FIG. 3H1 with a suitable reticle or mask 308, generally hereinafter referred to as a reticle 308. The reticle 308 includes opaque areas 309 and non-opaque (e.g., transparent) areas 310. In the case of a mask 308, the mask 308 may include opening area 310. In either case, the area 310 has a minimum width 312 that ranges between 10 microns and 30 microns, with a width 312 below this range being disadvantageous because it results in an inadequate pitch of the dielectric members 120, and with a width 312 above this range being disadvantageous because the concentration of dielectric members 120 becomes excessively high, causing problems such as limited current flow.

Each area 310 is vertically aligned with a corresponding cavity 307, meaning that a horizontal midpoint of the area 310 and a horizontal midpoint of the corresponding cavity 307 both lie along a vertical line that is orthogonal to the horizontal surface of the wafer 110. The cavity 307 has a width 314 that ranges between 10 microns and 30 microns, with a width 314 below this range being disadvantageous because a highly viscous dielectric material will have difficulty filling the cavity 307, and with a width 314 above this range being disadvantageous because the concentration of dielectric material in the metal member 118 becomes unacceptably high, causing problems such as restricted current flow. Regardless of the specific widths 312. 314, the width 312 is narrower than the width 314 by an amount ranging between 0 microns and 2.5 microns, with a width difference smaller than this range being disadvantageous because the reticle bias becomes uncontrollable, and with a width difference greater than this range being disadvantageous because the dielectric extends out of the dielectric area, causing an uneven surface to which the clip 124 must attach, and thus compromising the integrity of the mechanical connection between the clip 124 and the metal member 118. The portions of the dielectric member 120 within the cavities 307 are exposed, while the portions of the dielectric member 120 outside the cavities 307 are not exposed (or, in some examples, vice-versa, depending on the type of photolithographic technique being used). Because the width 312 is slightly narrower than the width 314 as described above, a small portion of the dielectric member 120 along the top rims of the cavities 307 remain in place, as numeral 316 indicates in FIG. 3I1. FIG. 3I2 is a top-down view of the structure of FIG. 3I1, in accordance with various examples. FIG. 3I3 is a perspective view of the structure of FIG. 3I1, in accordance with various examples.

FIG. 3J1 is a profile, cross-sectional view of the structure of FIG. 3I1, except that the dielectric member 120 has been developed and the unexposed areas of the dielectric member 120 have been removed (or, depending on the photolithographic technique used, the exposed areas of the dielectric member 120 are removed). The portions of the dielectric member 120 that remain are in the cavities 307 and are referred to herein as dielectric members 120. Each dielectric member 120 may have a downward-sloped top rim, as numeral 318 indicates, caused by the small portion of the dielectric member 120 that remained along the top rims of the cavities 307 prior to exposure (numeral 316 in FIG. 3I1). FIG. 3J2 is a top-down view of the structure of FIG. 3J1, in accordance with various examples. FIG. 3J3 is a perspective view of the structure of FIG. 3J1, in accordance with various examples.

The method 200 includes coupling a clip to the dielectric members and to the metal member with solder (216), and covering the metal member, the clip, and the die with a mold compound (218). FIG. 3K1 is a profile, cross-sectional view of the structure of FIG. 3J1, except that the clip 124 has been coupled to the dielectric members 120 and to the metal member 118 with solder paste 122, and the mold compound 126 covers the metal member 118, the clip 124, and the die 110, in accordance with various examples. In the event that numeral 110 referred to a wafer 110 instead of a die 110 (i.e., meaning that the steps 202-216 were performed during the wafer fabrication stage), the wafer 110 may be singulated (e.g., sawn) after step 216 to produce the die 110. FIG. 3K2 is a top-down view of the structure of FIG. 3K1, in accordance with various examples. FIG. 3K3 is a perspective view of the structure of FIG. 3K1, in accordance with various examples.

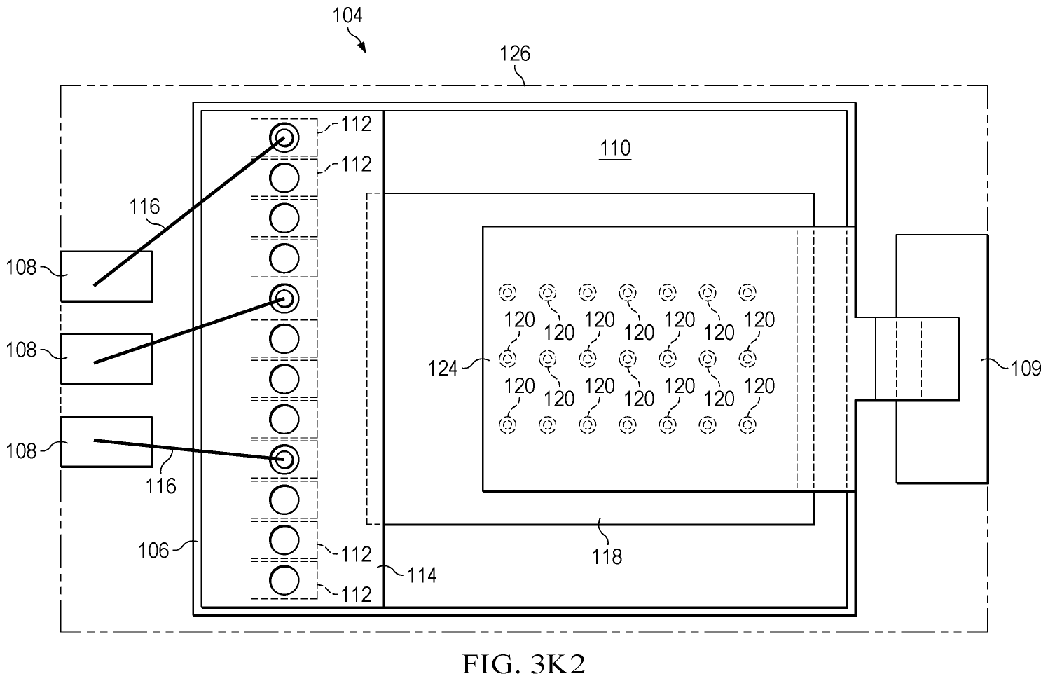

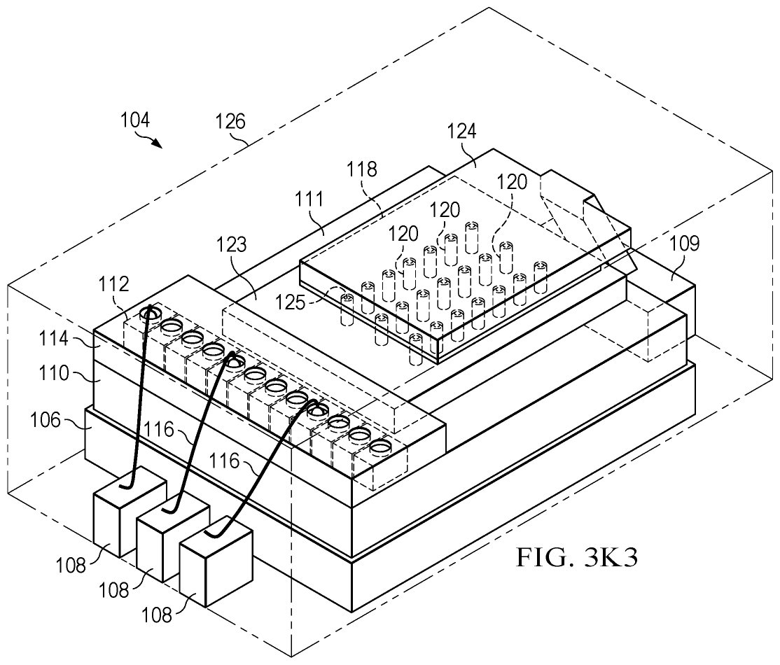

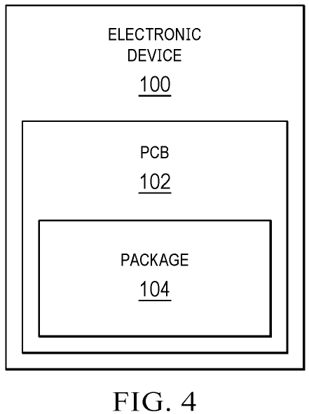

FIG. 4 is an electronic device 100 including a clip package having dielectric-filled bond pads, in accordance with various examples. The electronic device 100 may include, for example, a personal computer, a laptop, a desktop, a notebook, a tablet, a smartphone, an appliance (e.g., refrigerator, television, audio player, video player, video recorder, lighting device, etc.), an automobile, an aircraft, a spacecraft, etc. The electronic device 100 may comprise a printed circuit board (PCB) 102. The package 104 may be coupled to the PCB 102.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

In this description, unless otherwise stated, “about,” “approximately” or “substantially” preceding a parameter means being within +/−10 percent of that parameter. Modifications are possible in the described examples, and other examples are possible within the scope of the claims.

What is claimed is:

1. A package, comprising:
a semiconductor die including a device side having circuitry formed therein;
a first metal member on the device side of the die and having a top surface facing away from the die, the first metal member including a group of dielectric members, each dielectric member in the group of dielectric members extending at least partially through a thickness of the first metal member;
solder material contacting the top surface of the first metal member and top surfaces of the dielectric members in the group of dielectric members; and
a second metal member coupled to the solder material and to a conductive terminal of the package, the conductive terminal exposed to an exterior of the package.

2. The package of claim 1, wherein the group of dielectric members in the first metal member has a density ranging from 20% to 40%.

3. The package of claim 1, wherein the dielectric members comprise polyimide.

4. The package of claim 1, wherein the top surface of the first metal member lacks any dielectric material.

5. The package of claim 1, wherein the top surfaces of the dielectric members do not dip more than 2.88 microns below the top surface of the first metal member.

6. The package of claim 1, wherein the dielectric members of the group of dielectric members extend completely through the thickness of the first metal member.

7. The package of claim 1, wherein the second metal member is a clip.

8. The package of claim 1, wherein each dielectric member in the group of dielectric members has horizontal cross-sectional dimensions ranging from 10.42 microns to 16.18 microns.

9. A package, comprising:
a semiconductor die including a device side having circuitry formed therein;
a bond pad on the device side of the die and having a top surface facing away from the die, the bond pad including a group of polyimide members extending vertically through a thickness of the die, the group of polyimide members having a density ranging from 20% to 40%, each polyimide member in the group of polyimide members having a top surface that is approximately flush with the top surface of the bond pad, each polyimide member in the group of polyimide members having horizontal cross-sectional dimensions ranging from 10.42 microns to 16.18 microns;
solder paste contacting the top surfaces of the polyimide members in the group of polyimide members and the top surface of the bond pad;
a clip coupled to the solder paste and to a conductive terminal exposed to an exterior of the package; and
a mold compound covering the die, the bond pad, the solder paste, and the clip.

10. The package of claim 9, wherein the top surfaces of the polyimide members do not dip more than 2.88 microns below the top surface of the bond pad.

11. The package of claim 9, wherein the group of polyimide members extend completely through the thickness of the die.

12. A method for manufacturing a package, comprising:
sputtering a seed layer on a device side of a semiconductor wafer in which circuitry is formed;
covering the seed layer with a photoresist;
performing photolithography on the photoresist to form a cavity in the photoresist;
electroplating a metal member in the cavity of the photoresist and on the device side of the wafer;
removing the photoresist and parts of the seed layer to produce cavities within the metal member;
applying a dielectric member on the metal member and in the cavities within the metal member;
exposing the dielectric member using a reticle including first portions having a first degree of opacity and second portions having a second degree of opacity, and wherein the first portions of the reticle are vertically aligned with the cavities in the metal member; and
developing the dielectric member to remove portions of the dielectric member,
wherein the exposing and the developing cause portions of the dielectric member outside of the cavities in the metal member to be removed and portions of the dielectric member within the cavities of the metal member to have top surfaces that are approximately flush with a top surface of the metal member.

13. The method of claim 12, wherein the cavities in the metal member have a density ranging from 20% to 40%.

14. The method of claim 12, wherein the dielectric member comprises polyimide.

15. The method of claim 12, wherein the first degree of opacity is transparency.

16. The method of claim 12, wherein second degree of opacity is complete opacity.

17. The method of claim 12, wherein, after the exposing and the developing, no portion of the dielectric member remains outside of the cavities of the metal member.

18. The method of claim 12, wherein one of the first portions of the reticle is vertically aligned with a corresponding first cavity among the cavities of the metal member, and wherein a minimum width of the one of the first portions of the reticle is narrower than a width of the corresponding first cavity.

19. The method of claim 12, wherein the cavities of the metal member extend through a thickness of the wafer.

20. The method of claim 12, further comprising:
singulating the wafer to produce a die;
coupling the metal member to a package conductive terminal by a clip; and
covering the die, the metal member, and the clip with a mold compound.
